(19) United States
(12) Patent Application Publication
(10) Pub. No.: US 2008/0102587 A1
(43) Pub. Date: May 1, 2008

(54) METHOD OF MANUFACTURING HIGH VOLTAGE DEVICE

(75) Inventors: Ji Hyun Seo, Bucheon-si (KR); Dong Kee Lee, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/617,677

(22) Filed: Dec. 28, 2006

(30) Foreign Application Priority Data
Oct. 31, 2006 (KR) 2006-106483

(51) Int. Cl. H01L 21/336; H01L 21/4763

(52) U.S. Cl. 438/301; 438/629

(57) ABSTRACT

A method of manufacturing a high voltage device includes forming a junction region in a semiconductor substrate. An insulating layer is formed over the semiconductor substrate. A portion of the insulating layer is etched so that the junction region is exposed. Arsenic is implanted into the exposed junction region to form plug ion implantation regions. A plug is formed on the plug ion implantation regions into which arsenic has been implanted.

### CROSS-REFERENCES TO RELATED APPLICATIONS

The present application claims priority to Korean patent application number 2006-106483, filed on Oct. 31, 2006, which is incorporated herein by reference in its entirety.

### BACKGROUND OF THE INVENTION

The present invention relates, in general, to a method of manufacturing a high voltage device and, more particularly, to a method of manufacturing a high voltage device that exhibits high breakdown voltage and low leakage current characterstics.

In order to operate a semiconductor device, power must be supplied. Semiconductor devices that operate at low voltages have been developed in order to conserve consumption power. However, a voltage higher than a supplied voltage may be required within a semiconductor device. For example, in a flash memory device, a voltage that is higher than an externally supplied power supply voltage is used during a program operation or an erase operation. Thus, a high voltage is generated by raising the level of the external power supply voltage supplied through a pumping operation.

A semiconductor device almost always includes transistors. The transistors may be classified into low voltage transistors operating at a low voltage and high voltage transistors operating at a high voltage. A junction region (e.g., a source or a drain) of the high voltage transistor is formed to have a different shape from that of the low voltage transistor using a different method. Furthermore, problems may result in the high voltage transistor that are not existent in the low voltage transistor due to the high voltage.

For example, the high voltage transistor requires a high breakdown voltage characteristic when compared with the low voltage transistor. Furthermore, in the high voltage transistor the leakage current must be minimized. The leakage current is generated as the level of integration increases thereby shortening channel length. In addition, if contact resistance between the junction region and a contact plug formed on the junction region is high, a voltage drop occurs, and a high voltage cannot be transferred efficiently.

### BRIEF SUMMARY OF THE INVENTION

A method of manufacturing a high voltage device causes the high voltage device to be formed with a shallow junction. The high voltage device exhibits a high breakdown voltage characteristic, a low leakage current characteristic and an enhanced resistive contact characteristic.

In one embodiment, a method of manufacturing a high voltage device includes forming a junction region in a semiconductor substrate. An insulating layer is formed over the semiconductor substrate. A portion of the insulating layer is etched so that the junction region is exposed. Arsenic (As) is implanted into the exposed junction region to form plug ion implantation regions. A plug is formed on the plug ion implantation regions into which arsenic has been implanted.

In another embodiment, a method of manufacturing a high voltage device includes forming a junction region in a semiconductor substrate. An insulating layer is formed over the semiconductor substrate. A portion of the insulating layer is etched so that the junction region is exposed. Antimony (Sb) is implanted into the exposed junction region to form plug ion implantation regions. A plug is formed on the plug ion implantation regions into which antimony has been implanted.

In yet another embodiment, a method of manufacturing a high voltage device includes forming a transistor in a semiconductor substrate. An insulating layer is formed over the semiconductor substrate. A portion of the insulating layer is etched so that a junction region of the transistor is exposed. Arsenic is implanted into the exposed junction region to form plug ion implantation regions. A plug is formed on the plug ion implantation regions into which arsenic has been implanted.

In still another embodiment, a method of manufacturing a high voltage device includes forming a transistor in a semiconductor substrate. An insulating layer is formed over the semiconductor substrate. A portion of the insulating layer is etched so that a junction region of the transistor is exposed. Antimony is implanted into the exposed junction region to form plug ion implantation regions. A plug is formed on the plug ion implantation regions into which antimony has been implanted.

### BRIEF DESCRIPTION OF THE DRAWINGS

FIGS. 1A to 1D are cross-sectional views illustrating a method of manufacturing a high voltage device according to an embodiment of the present invention.

FIGS. 2A to 2D are cross-sectional views illustrating a method of manufacturing a high voltage device according to another embodiment of the present invention.

FIG. 3 is a characteristic graph showing the difference in the concentration of arsenic and a phosphor implanted by a plug ion implantation process.

FIG. 4 is a characteristic graph showing the difference in the breakdown voltage when arsenic and a phosphor are implanted by a plug ion implantation process.

### DESCRIPTION OF SPECIFIC EMBODIMENTS

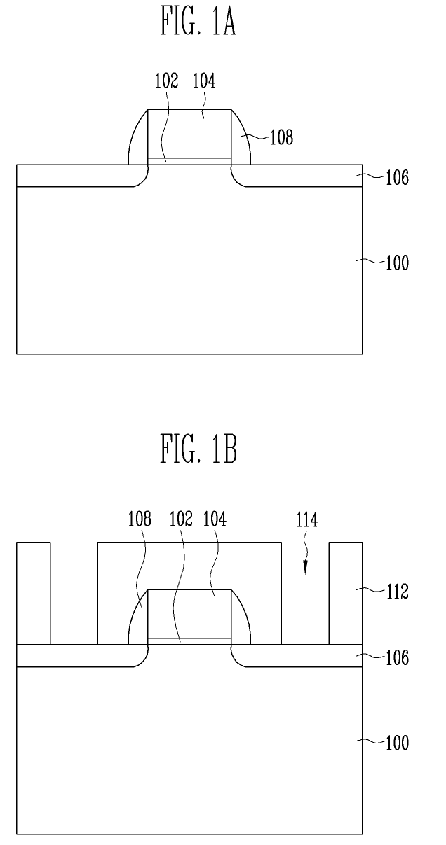

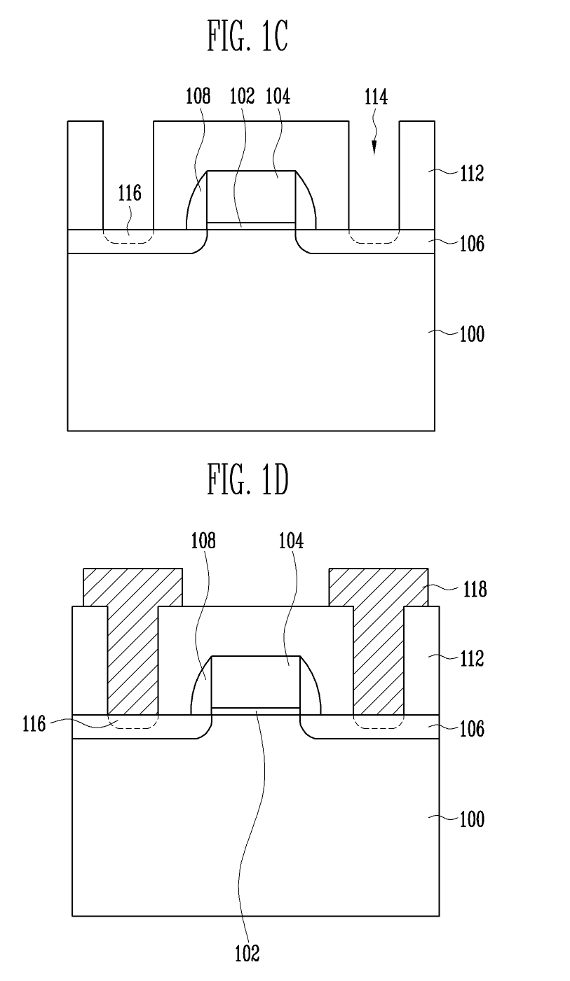

Specific embodiments will be described with reference to the accompanying drawings. FIGS. 1A to 1D are cross-sectional views illustrating a method of manufacturing a high voltage device according to an embodiment of the present invention.

Referring to FIG. 1A, a transistor is formed in an active region of a semiconductor substrate 100 in which a well (not shown) and an isolation layer (not shown) are formed. A gate insulating layer 102 and a gate 104 are formed over the semiconductor substrate 100. A first junction region 106 is formed in the semiconductor substrate 100 at the edges of the gate 104. The first junction region 106 becomes the source/drain of the transistor, and a second junction region (not shown) formed in the well region becomes a well pick-up region.

A spacer 108 is formed on sidewalls of the gate 104. The first junction region 106 is formed by implanting a 5-valence impurity, such as a phosphor or arsenic (As) in the case of a NMOS transistor. In one embodiment, the first junction region 106 may be formed by implanting the 5-valence impurity with a concentration of 5.0×10¹² atoms/cm² or less at an energy of approximately 70 KeV. Furthermore, the first junction region 106 may be formed by implanting the 5-valence impurity at an angle of approximately 3 to approximately 7 degrees while rotating the semiconductor substrate 100. The first junction region 106 is formed to a level that contacts bottom edges of the gate 104.

Referring to FIG. 1B, an insulating layer 112 is formed over the semiconductor substrate 100. A portion of the insulating layer 112 is etched so that the first junction region 106 is exposed, thereby forming contact holes 114.

Referring to FIG. 1C, a plug ion implantation process is performed on the first junction region 106 that is exposed through the contact holes 114, thereby forming plug ion implantation regions 116. The plug ion implantation regions 116 improve an adhesive characteristic with a plug, which is formed in a subsequent process as described below. The plug ion implantation regions 116 are formed by implanting an impurity capable of forming a resistive contact.

The plug ion implantation regions 116 may be formed by implanting arsenic. In one embodiment, the plug ion implantation regions 116 are formed by implanting arsenic at a concentration of approximately 1.0×10¹⁴ atoms/cm² to approximately 5.0×10¹⁴ atoms/cm² at an ion implantation energy of approximately 5 KeV to approximately 15 KeV. Arsenic is preferably implanted vertically. Alternatively, antimony (Sb) may be implanted instead of arsenic. The plug ion implantation regions 116 may be formed by implanting antimony at a concentration of approximately 1.0×10¹⁴ atoms/cm² to approximately 5.0×10¹⁴ atoms/cm² at an ion implantation energy of approximately 5 KeV to approximately 15 KeV.

After the plug ion implantation regions 116 are formed, an annealing process is performed to activate the implanted impurity (arsenic or antimony). The annealing process may be performed using a rapid thermal process in a temperature range of approximately 900 to approximately 950 degrees Celsius.

Referring to FIG. 1D, a plug 118 is formed within each of the contact holes 114 on the plug ion implantation regions 116. The plug 118 may be formed using polysilicon or tungsten. After a conductive layer (e.g., polysilicon or tungsten) is formed on the surface of the insulating layer 112 so that the contact holes 114 are filled, an etch process is performed so that the conductive layer remains within the contact holes 114. The conductive layer may have a width that is wider than a width of the contact hole 114. A metal line may also be formed by allowing the conductive layer to remain on the insulating layer 112 in a specific pattern.

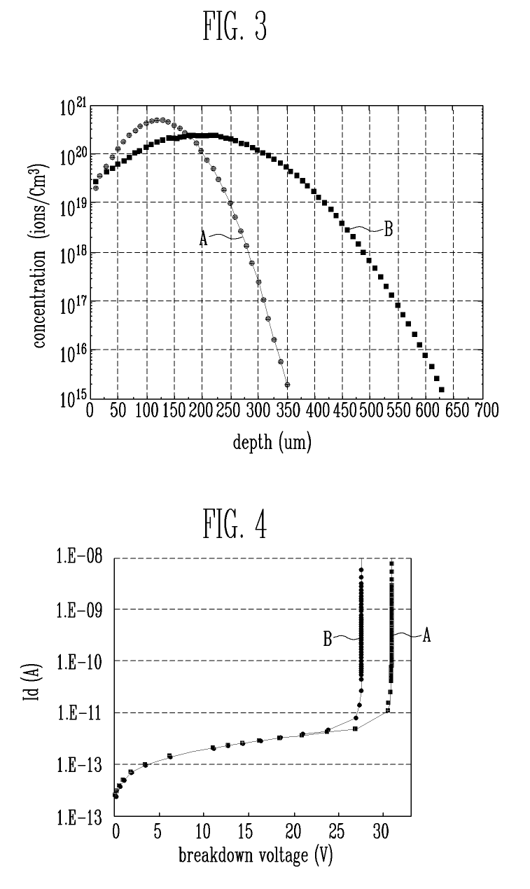

After the plug ion implantation regions 116 are formed by implanting arsenic or antimony according to the above method, a plug 118 is formed. Accordingly, a resistive contact is formed by the plug ion implantation regions 116, thereby lowering contact resistance. Alternatively, arsenic or antimony having a low diffusivity may be implanted instead of a phosphor to form the plug ion implantation regions 116. Thus, a shallow junction may be formed, and a high breakdown voltage characteristic, a low leakage current characteristic and an enhanced resistive contact characteristic may be obtained when compared with the implanting of a phosphor. Such a characteristic difference is described below with reference to the graphs in FIGS. 3 and 4.

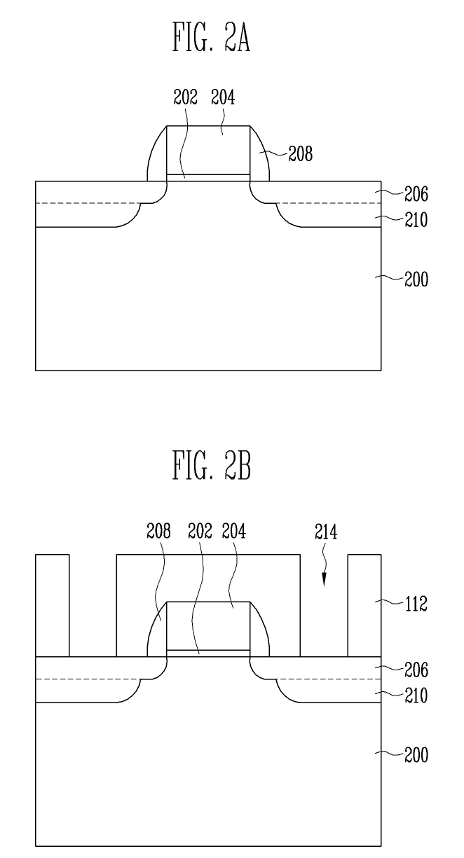

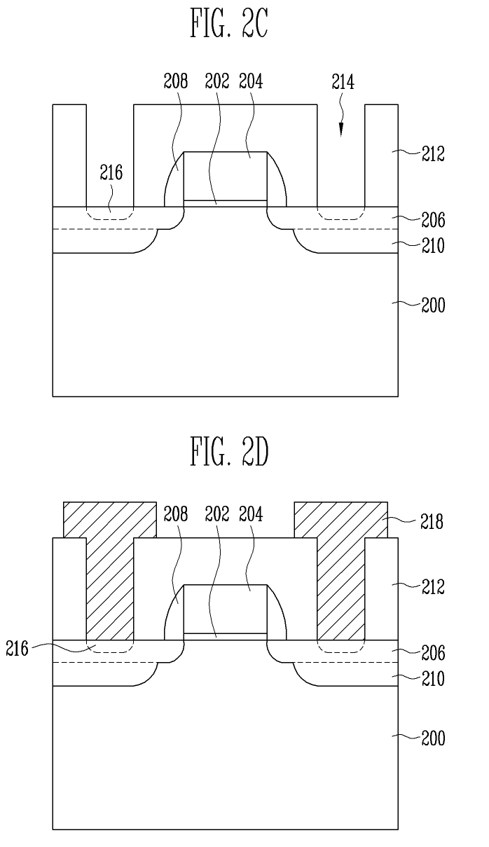

FIGS. 2A to 2D are cross-sectional views illustrating a method of manufacturing a high voltage device according to another embodiment of the present invention.

Referring to FIG. 2A, a transistor is formed in an active region of a semiconductor substrate 200 in which a well (not shown) and an isolation layer (not shown) are formed. A gate insulating layer 202 and a gate 204 are formed over the semiconductor substrate 200. A first junction region 206 is formed in the semiconductor substrate 200 proximate to the edges of the gate 204. The first junction region 206 is a junction region for forming a lightly doped drain structure, and becomes the source/drain of the transistor.

A spacer 208 is formed on sidewalls of the gate 204. A second junction region 210 is formed in the semiconductor substrate 200 proximate to the edges of the spacer 208. The first and second junction regions 206 and 210 become the source/drain of the transistor. The first and second junction regions 206 and 210 are formed by implanting a 5-valence impurity, such as a phosphor or arsenic in the case of a NMOS transistor. The second junction region 210 is formed in the semiconductor substrate 200 at a greater depth than the first junction region 206. A greater amount of the impurity is implanted into the second junction region 210 than the amount that is implanted into the first junction region 206. In one embodiment, the first and second junction regions 206 and 210 may be formed by implanting the 5-valence impurity with a concentration of 5.0×10¹² atoms/cm² or less and at an energy of approximately 70 KeV. Furthermore, the first junction region 206 may be formed by implanting the 5-valence impurity at an angle of approximately 3 to approximately 7 degrees while rotating the semiconductor substrate 200. The first junction region 206 is formed at a level that is proximate to bottom edges of the gate 204.

Referring to FIG. 2B, an insulating layer 212 is formed over the semiconductor substrate 200. A portion of the insulating layer 212 is etched to form contact holes 214 so that a portion of the first junction region 206 is exposed.

Referring to FIG. 2C, a plug ion implantation process is performed on the first junction region 206 that is exposed through the contact holes 214, thereby forming plug ion implantation regions 216. The plug ion implantation regions 216 improve an adhesive characteristic with a plug, which is formed in a subsequent process described below. The plug ion implantation regions 216 are formed by implanting an impurity that forms a resistive contact. The plug ion implantation regions 216 may be formed by implanting arsenic. In one embodiment, the plug ion implantation regions 216 are formed by implanting arsenic at a concentration of approximately 1.0×10¹⁴ atoms/cm² to approximately 5.0×10¹⁴ atoms/cm² at an ion implantation energy of approximately 5 KeV to approximately 15 KeV. Arsenic is preferably implanted vertically. Alternatively, antimony may be implanted instead of arsenic. In one embodiment, the plug ion implantation regions 216 may be formed by implanting antimony at a concentration of approximately 1.0×10¹⁴ atoms/cm² to approximately 5.0×10¹⁴ atoms/cm² at an ion implantation energy of approximately 5 KeV to approximately 15 KeV. By forming the plug ion implantation regions 216, the source/drain has a triple doped drain structure consisting of the first junction region 206, the second junction region 210 and the plug ion implantation regions 216.

After the plug ion implantation regions 216 are formed, an annealing process is performed to activate the implanted impurity (arsenic or antimony). The annealing process may be performed using a rapid thermal process in a temperature range of approximately 900 to approximately 950 degrees Celsius.

Referring to FIG. 2D, a plug 218 is formed within each of the contact holes 214 over the plug ion implantation regions 216. The plug 218 may be formed using polysilicon or tungsten. After a conductive layer (polysilicon or tungsten) is formed on the surface of the insulating layer 212 so that the contact holes 214 are filled, an etch process is performed such that the conductive layer remains within the contact holes 214. The conductive layer may have a width that is wider than a width of the contact hole 214. A metal line may also be formed by allowing the conductive layer to remain on the insulating layer 216 in a specific pattern.

FIG. 3 is a characteristic graph showing the difference in the concentration of arsenic and a phosphor implanted by a plug ion implantation process.

Referring to FIG. 3, a concentration graph A illustrates when a phosphor is implanted during the plug ion implantation process, and a concentration graph B illustrates when arsenic is implanted during the plug ion implantation process. From the two graphs A and B, it can be seen that in the case of the phosphor, the diffusivity against heat is excellent compared with arsenic. Although the phosphor is implanted at a shallow depth during the plug ion implantation process, the surface concentration of the phosphor on the semiconductor substrate decreases as the phosphor is diffused into the semiconductor substrate by means of a subsequent thermal process. In contrast, it can be seen that in the case of arsenic, since a diffusion characteristic against heat is low, the surface concentration of arsenic on the semiconductor substrate is higher compared to the phosphor. In addition, arsenic is diffused only up to a shallow depth.

Accordingly, when arsenic is implanted rather than the phosphor, a high concentration may be maintained on the substrate surface, an excellent resistive contact characteristic may be obtained, and the plug ion implantation regions may be formed at a shallow depth. Similarly, when antimony is implanted instead of arsenic, the plug ion implantation regions are formed on the substrate surface at a high concentration and a shallow depth, compared to the phosphor.

FIG. 4 is a characteristic graph showing the difference in the breakdown voltage when arsenic and a phosphor are implanted by a plug ion implantation process.

Referring to FIG. 4, a breakdown characteristic graph A illustrates when a phosphor is implanted during the plug ion implantation process, and a breakdown characteristic graph B illustrates when arsenic is implanted during the plug ion implantation process.

From the two graphs A and B, it can be seen that when arsenic is implanted rather than the phosphor, the breakdown voltage is approximately 2 to 3 V higher and a good breakdown characteristic may be obtained. Similarly, it can be seen that when antimony is implanted instead of arsenic, a high breakdown voltage characteristic may be obtained, compared to the phosphor.

Meanwhile, electrical characteristics exhibited when a phosphor is implanted and when arsenic is implanted are listed in the following table.

| | Phosphor | Arsenic |
|---|---|---|
| Threshold Voltage | 0.682 | 0.679 |
| I_{DS} | 22.4 | 22.1 |
| Breakdown Voltage | 23.26 | 25.77 |
| Leakage Current | 53.62 | 21.26 |

The above table illustrates performance characteristics when a phosphor and arsenic are implanted with a concentration of 5×10¹⁴ atoms/cm² during the plug ion implantation process when a channel width is 10 micrometer and channel length is 0.9 micrometer. As can be seen from the table, there is no significant difference in the threshold voltage and the drain saturation current (I_{DS}) when either a phosphor or arsenic is implanted. However, it can be seen that the breakdown voltage is higher by approximately 2.5V when a phosphor is implanted when compared with arsenic.

It can also be seen that the leakage current is reduced by up to a half when arsenic is implanted compared with the phosphor. This is because the diffusivity of arsenic is lower than that of a phosphor, and horizontal diffusion into the bottom of the gate is minimized.

If the plug is formed using tungsten, an excellent electrical characteristic as described above may be obtained by implanting arsenic instead of a phosphor during the plug ion implantation process.

As described above, according to the present invention, a transistor has a junction region that is formed on the semiconductor substrate. Before the contact plug is formed on the junction region, arsenic, having a small diffusivity against heat, is implanted into the junction region using a plug ion implantation process, thereby forming a resistive contact. Accordingly, a shallow junction may be formed, and a high breakdown voltage characteristic, a low leakage current characteristic and an enhanced resistive contact characteristic may be obtained.

The above embodiment of the present invention is illustrative and not limitative. Various alternatives and equivalents are possible. Other additions, subtractions, or modifications are obvious in view of the present disclosure and are intended to fall within the scope of the appended claims.

What is claimed is:

1. A method of manufacturing a high voltage device, the method comprising:
forming a junction region in a semiconductor substrate;
forming an insulating layer over the semiconductor substrate;
etching a portion of the insulating layer to expose the junction region;
implanting a 5-valence impurity into the exposed junction region to form plug ion implantation regions; and
forming a plug on the plug ion implantation regions.

2. The method of claim 1, wherein the 5-valence impurity is arsenic or antimony.

3. The method of claim 2, wherein the arsenic is implanted at a concentration that ranges from approximately 1.0×10¹⁴ atoms/cm² to approximately 5.0×10¹⁴ atoms/cm².

4. The method of claim 2, wherein the arsenic is implanted at an ion implantation energy of approximately 5 KeV to approximately 15 KeV.

5. The method of claim 2, wherein the antimony is implanted at a concentration that ranges from approximately 1.0×10¹⁴ atoms/cm² to approximately 5.0×10¹⁴ atoms/cm².

6. The method of claim 2, wherein the antimony is implanted at an ion implantation energy of approximately 5 KeV to approximately 15 KeV.

7. The method of claim 1, further comprises performing a thermal treatment process after the plug ion implantation regions are formed.

8. The method of claim 7, wherein the thermal treatment process comprises an annealing process that is performed by a rapid thermal process in a temperature range of approximately 900 to approximately 950 degrees Celsius.

9. The method of claim 1, wherein the plug is formed from tungsten.

10. A method of manufacturing a high voltage device, the method comprising:
forming a transistor in a semiconductor substrate;
forming an insulating layer over the semiconductor substrate;
etching a portion of the insulating layer to expose a junction region of the transistor;
implanting a 5-valence impurity into the exposed junction region to form plug ion implantation regions; and
forming a plug on the plug ion implantation regions.

11. The method of claim 10, wherein the junction region of the transistor includes a lightly doped drain structure, and further includes a triple doped drain structure corresponding to the plug ion implantation regions.

12. The method of claim 10, wherein the 5-valence impurity is an arsenic or an antimony.

13. The method of claim 12, wherein the arsenic is implanted at a concentration that ranges from approximately 1.0×10¹⁴ atoms/cm² to approximately 5.0×10¹⁴ atoms/cm².

14. The method of claim 12, wherein the arsenic is implanted at an ion implantation energy of approximately 5 KeV to approximately 15 KeV.

15. The method of claim 12, wherein the antimony is implanted at a concentration that ranges from approximately 1.0×10¹⁴ atoms/cm² to approximately 5.0×10¹⁴ atoms/cm².

16. The method of claim 12, wherein the antimony is implanted at an ion implantation energy of approximately 5 KeV to approximately 15 KeV.

17. The method of claim 10, further comprises performing a thermal treatment process after the plug ion implantation regions are formed.

18. The method of claim 17, wherein the thermal treatment process comprises an annealing process that is performed by a rapid thermal process in a temperature range of approximately 900 to approximately 950 degrees Celsius.

19. The method of claim 10, wherein the plug is formed from tungsten.
